(19) United States
(12) Patent Application Publication
(10) Pub. No.: US 2025/0076385 A1
(43) Pub. Date: Mar. 6, 2025

(54) BATTERY CELL DESIGN TESTING FIXTURE

(71) Applicant: GM Global Technology Operations LLC, Detroit, MI (US)

(72) Inventors: Michelle H. Wiebenga, Farmington Hills, MI (US); Erik Brandon Golm, Sterling Heights, MI (US); Lei Wang, Rochester Hills, MI (US); Vamakshi Yadav, Sterling Heights, MI (US)

(21) Appl. No.: 18/457,719

(22) Filed: Aug. 29, 2023

(51) Int. Cl. G01R 31/36

(52) U.S. Cl. CPC G01R 31/3644

(57) ABSTRACT

A battery cell chemistry test fixture includes a housing including a battery cell chamber. A first electric terminal is electrically connectable to a battery cell in the battery cell chamber. A second electric terminal is electrically connectable to the battery cell in the battery cell chamber. A plurality of sensor connectors is mounted to the housing. The plurality of sensor connectors include at least a gas sampling connector, a pressure sensor connector, and a valve connector, each of the gas sampling connector, the pressure sensor connector, and the valve connector being fluidically connected with the battery cell chamber.

### INTRODUCTION

The subject disclosure relates to the art of test fixtures and, more particularly, to a test fixture for testing battery cell designs.

Battery cell chemistry is designed to meet a number of criteria such as power storage capability, charging performance, and discharging performance. Operating temperatures, (e.g, temperatures reached in the battery cell during charging and discharging cycles), and operating pressures, (e,g, electrolyte pressures created during charging and discharging) are factors that may influence energy storage, charging speed, and discharging depth.

To test cell chemistry, a sample cell is created and placed in a test fixture. The sample cell is connected to an electrical source and then cycled. Currently available test fixtures have limited usefulness. At present, currently available fixtures allow voltage response to be monitored while the cell is cycling. In addition to monitoring voltage, currently available fixtures may provide access to sample and/or monitor gas produced by the cell while being cycled. Unfortunately, other parameters of interest such as cell temperature, cell pressure, and the like are not currently sampleable with existing fixtures. Accordingly, it is desirable to create a test fixture that provides greater flexibility for monitoring and sampling battery chemistry.

### SUMMARY

A battery cell chemistry test fixture, in accordance with a non-limiting example, includes a housing including a battery cell chamber. A first electric terminal is electrically connectable to a battery cell in the battery cell chamber. A second electric terminal is electrically connectable to the battery cell in the battery cell chamber. A plurality of sensor connectors is mounted to the housing. The plurality of sensor connectors include at least a gas sampling connector, a pressure sensor connector, and a valve connector, each of the gas sampling connector, the pressure sensor connector, and the valve connector being fluidically connected with the battery cell chamber.

In addition to one or more of the features described herein the housing includes a first housing portion and a second housing portion coupled to the first housing portion, the battery cell chamber being formed in the first housing portion.

In addition to one or more of the features described herein the first electric terminal is supported on the first housing portion.

In addition to one or more of the features described herein a biasing member is arranged in the battery cell chamber, the biasing member being arranged to urge a first battery cell portion into contact with the first housing portion and establish an electrical connection with the first electric terminal.

In addition to one or more of the features described herein a second battery cell portion is electrically connected to the second housing portion through the biasing member, the second electrical terminal being electrically connected to the second housing portion.

In addition to one or more of the features described herein an insulating member electrically isolating the first housing portion and the second housing portion.

In addition to one or more of the features described herein the second housing portion includes a first passage fluidically connecting the gas sampling connector and the battery cell chamber, a second passage fluidically connecting the pressure sensor connector with the battery cell chamber, and a third passage fluidically connecting the valve connector and the battery cell chamber.

In addition to one or more of the features described herein the second housing portion includes a central passage fluidically connected to the battery cell chamber.

In addition to one or more of the features described herein a third housing portion connected to the second housing portion, the plurality of sensor connectors being provided in the third housing portion.

In addition to one or more of the features described herein the third housing portion includes a first passage fluidically connecting the gas sampling connector and the central passage, a second passage fluidically connecting the pressure sensor connector with the central passage, and a third passage fluidically connecting the valve connector and the central passage.

In addition to one or more of the features described herein a gas permeable membrane is disposed between the second housing portion and the third housing portion, the gas permeable membrane forming a liquid barrier isolating the central passage from each of the first passage, the second passage, and the third passage.

In addition to one or more of the features described herein the second electric terminal is supported on the second housing portion.

In addition to one or more of the features described herein each of the gas sampling connector, the pressure sensor connector, and the valve connector is mounted to the first housing portion.

In addition to one or more of the features described herein a first clamping block arranged in the battery cell chamber, the first clamping block being biased toward the second housing portion.

In addition to one or more of the features described herein a second clamping block arranged in the second housing portion, the first clamping block being biased toward the second clamping block.

In addition to one or more of the features described herein a battery cell arranged in the battery cell chamber, the battery cell including a first terminal and a second terminal, the first terminal and the second terminal being arranged between the first clamping block and the second clamping block.

In addition to one or more of the features described herein a first conductor including a first electrically conductive member extends through the first electric terminal and a second conductor including a second electrically conductive member extends through the second electric terminal, the first electrically conductive member engaging the first terminal and the second electrically conductive member engaging the second terminal.

In addition to one or more of the features described herein a biasing member arranged in the battery cell chamber, the biasing member being arranged to urge a battery cell toward the second housing portion.

In addition to one or more of the features described herein the biasing member is arranged between first and second non-electrically conductive spacers.

In addition to one or more of the features described herein each of the first electric terminal and the second electric terminal are connected to the first housing portion.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a perspective view of a battery cell design test fixture, in accordance with a non-limiting example;

FIG. 2 is a cross-sectional view of the battery cell design test fixture of FIG. 1 taken through the line 2-2, in accordance with a non-limiting example;

FIG. 3 is a perspective view of a battery cell design test fixture, in accordance with another non-limiting example;

FIG. 4 is a cross-sectional view of the battery cell design test fixture of FIG. 3 taken through the line 4-4, in accordance with a non-limiting example;

FIG. 5 is a perspective view of a battery cell design test fixture, in accordance with yet another non-limiting example;

FIG. 6 is a disassembled view of the battery cell chemistry test fixture of FIG. 5, in accordance with a non-limiting example;

FIG. 7 is a cross-sectional view of the battery cell design test fixture of FIG. 5 taken through the line 7-7, in accordance with a non-limiting example;

FIG. 8 is a cross-sectional view of the battery cell design test fixture of FIG. 5 taken through the line 8-8, in accordance with a non-limiting example;

FIG. 9 is a cross-sectional view of the battery cell design test fixture of FIG. 5 taken through the line 9-9, in accordance with a non-limiting example;

FIG. 10 is a perspective view of a battery cell design test fixture, in accordance with still yet another non-limiting example; and

FIG. 11 is a cross-sectional view of the battery cell design test fixture of FIG. 10 taken through the line 11-11, in accordance with a non-limiting example.

### DETAILED DESCRIPTION

The following description is merely exemplary in nature and is not intended to limit the present disclosure, its application or uses. It should be understood that throughout the drawings, corresponding reference numerals indicate like or corresponding parts and features.

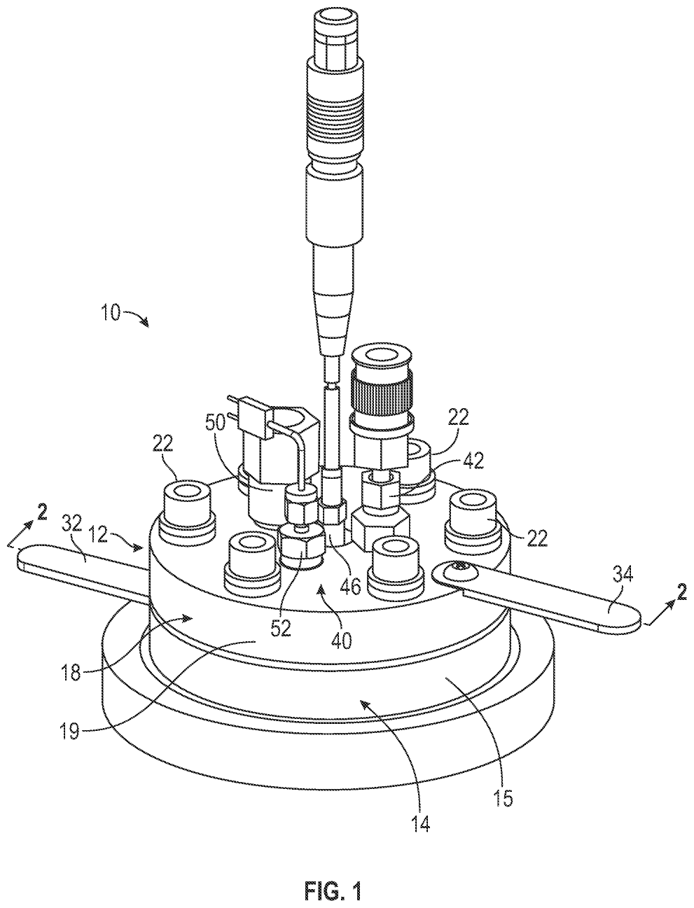

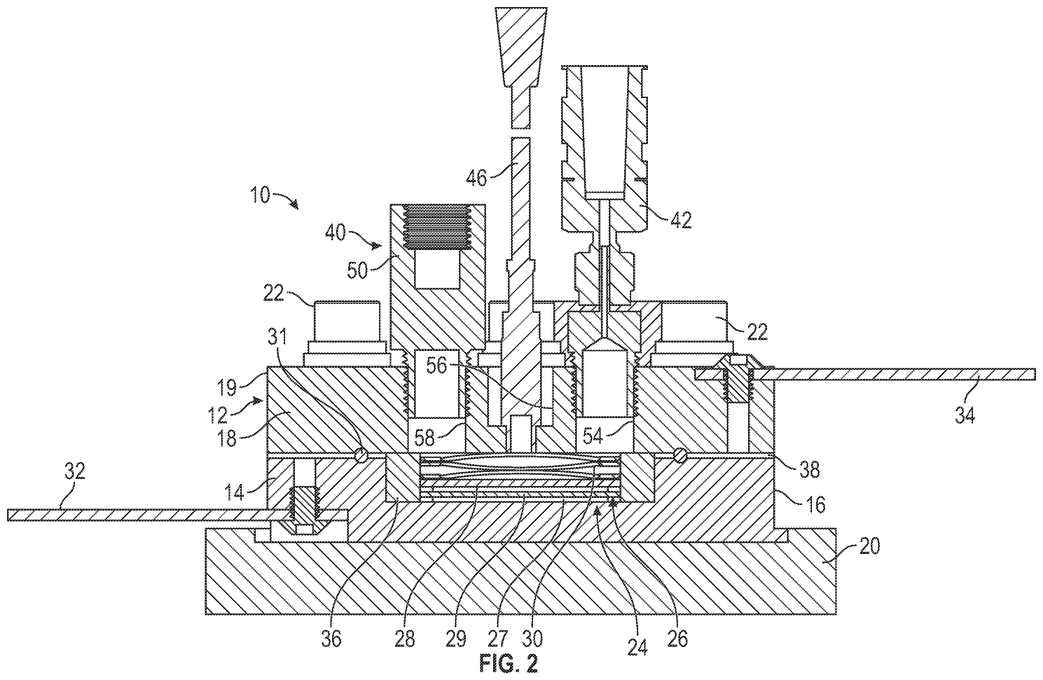

Referring to FIGS. 1 and 2, a test fixture, in accordance with a non-limiting example, indicated at 10 includes a housing 12 having a first housing portion 14 including a first outer annular surface 15, and a second housing portion 18 including a second outer annular surface 19. A plurality of mechanical fasteners, such as shown at 22, join first housing portion 14 and second housing portion 18. Test fixture 10 may be supported upon an electrically insulating surface 20.

First housing portion 14 includes a battery cell chamber 24 into which a test battery cell 26 may be introduced. In a non-limiting example, battery cell chamber 24 is circular. Battery cell 26 includes a first element 27 which may be a cathode electrically connected to first housing portion 14 and a second element 28 which may be an anode, separated by an insulating separator 29. A liquid electrolyte may be added into the battery cell chamber 24. A biasing member 30 is arranged at second element 28. Biasing member 30 electrically connects second element 28 with second housing portion 18. An “O”-ring 31 may be arranged between first housing portion 14 and second housing portion 18 in order to form a seal about battery chamber 24.

A first electric terminal 32 is connected to first housing portion 14 and a second electric terminal 34 is connected to second housing portion 18. First electric terminal 32 and second electric terminal 34 may alternatively be connected to a load and a source of power in order to cycle battery cell 26. First electric terminal 32 is electrically connected to first element 27 of battery cell 26 while second electric terminal 34 is electrically connected with second element 28 of battery cell 26. In a non-limiting example, an electrically insulating element or spacer 36 is arranged in battery cell chamber 24. Spacer 36 centers battery cell 26 in battery cell chamber 24. An electrically insulating member 38, FIG. 2, is arranged between first housing portion 14 and second housing portion 18.

In a non-limiting example, a plurality of sensor connectors 40 is provided on second housing portion 18. Sensor connectors 40 include a gas sampling connector 42, a pressure sensor connector 46, a valve connector 50, and a thermocouple connector 52 (FIG. 1). In a non-limiting example, a first passage 54 extends between and fluidically connects gas sampling connector 42 and battery cell chamber 24. A second passage 56 extends between and fluidically connects pressure sensor connector 46 and battery cell chamber 24. A third passage 58 extends between and fluidically connects valve connector 50 and battery cell chamber 24. Valve connector 50 may support a check valve, a pressure relief valve, or the like.

In a non-limiting example, each sensor connector 40 supports a fitting or interface for a corresponding sensor that may receive sample fluids, such as gas, from battery cell 26. The amount of electrolyte in battery cell chamber 24 may out gas while battery cell 26 cycles. Gas escaping from battery cell 26 passes though first, second, and third passages to a corresponding one of the plurality of sensor connectors 40. The gas may be sampled, measured, and tested, and in order to evaluate battery cell performance.

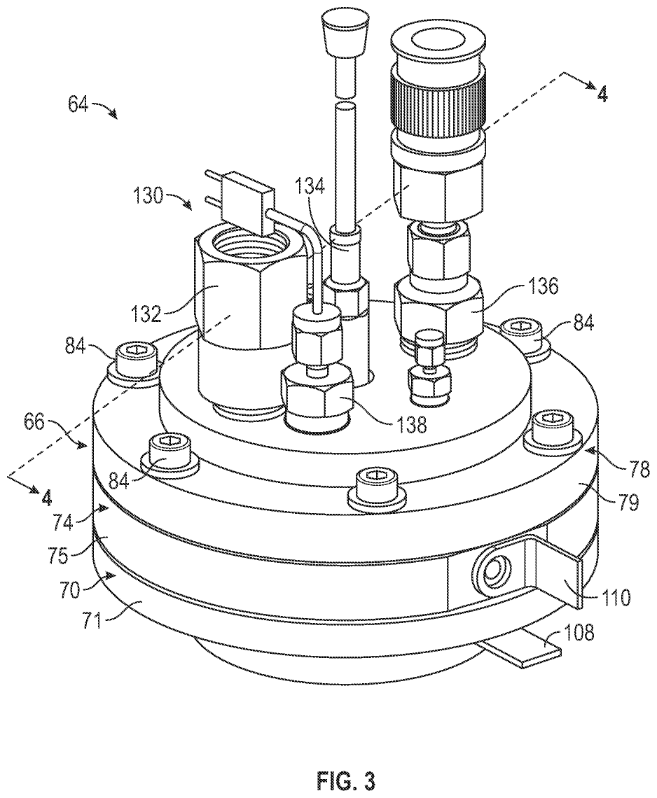

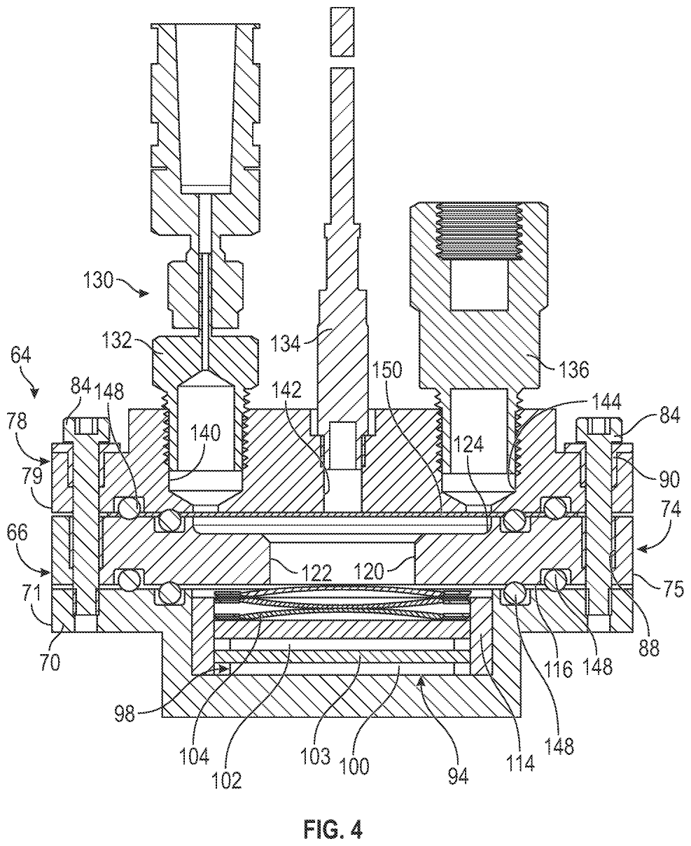

Reference will now follow to FIGS. 3 and 4 in describing a test fixture 64 in accordance with another non-limiting example. Test fixture 64 includes a housing 66 having a first housing portion 70 including a first outer annular surface 71, a second housing portion 74 including a second outer annular surface 75, and a third housing portion 78 including a third outer annular surface 79. A plurality of mechanical fasteners 84 join first housing portion 70, second housing portion 74, and third housing portion 78. In a non-limiting example, second housing portion 74 and third housing portion 78 are electrically isolated from first housing portion 70. Towards that end, electrically insulative spacers such as shown at 88 and 90 electrically isolate mechanical fasteners 84 from second housing portion 74 and third housing portion 78.

In a non-limiting example, first housing portion 70 includes a battery cell chamber 94 having a generally circular or annular shape. A battery cell 98 is arranged in battery cell chamber 94. Battery cell 98 includes a first element 100 which may be a cathode and a second element 102 which may be an anode. First element 100 and second element 102 may be separated by an electrically insulating separator 103. First element 100 is in direct contact with and thus electrically connected to first housing portion 70. Second element 102 is electrically connected to second housing portion 74 through a biasing member 104. With this arrangement, a first electric terminal 108 is connected to first housing portion 70 and first element 100 and a second electric terminal 110 is connected to second housing portion 74 and second element 102. Battery cell 98 is centered in battery cell chamber 94 through an insulating element 114. A liquid electrolyte may be added into the battery cell chamber 94. Second housing portion 74 is electrically isolated from first housing portion 70 through an insulating member 116.

In a non-limiting example, second housing portion 74 includes a central passage 120 having a first end 122 arranged adjacent to battery cell chamber 94 and a second end 124 arranged at third housing portion 78. Central passage 120 carries gases from battery cell chamber 94 towards third housing portion 78 as will be discussed more fully herein. Third housing portion 78 supports a plurality of sensor connectors 130. Sensor connectors 130 include, in accordance with a non-limiting example, a gas sampling sensor connector 132, a pressure sensor connector 134, a valve connector 136, and a thermocouple connector 138 (FIG. 3).

In a non-limiting example, third housing portion 78 includes a first passage 140 fluidically connected to gas sampling connector 132 and central passage 120 in second housing portion 74, a second passage 142 fluidically connected between pressure sensor connector 134 and central passage 120, and a third passage 144 fluidically connected between pressure sensor connector 134 and central passage 120. With this arrangement, gas escaping from battery cell 98 passes from battery cell chamber 94, through central passage 120, and into first passage 140, second passage 142, and third passage 144 to corresponding ones of the plurality of sensor connectors 130. The gas may be sampled, measured, and tested in order to evaluate battery cell performance. Housing 66 is sealed by a plurality of O-rings 148. In a non-limiting example, a gas permeable membrane 150 is arranged between second housing portion 74 and third housing portion 78. Gas permeable membrane 150 allows gas to pass to plurality of sensor connectors 130 while, at the same time, forms a liquid barrier that prevents any electrolyte from passing into third housing portion 78.

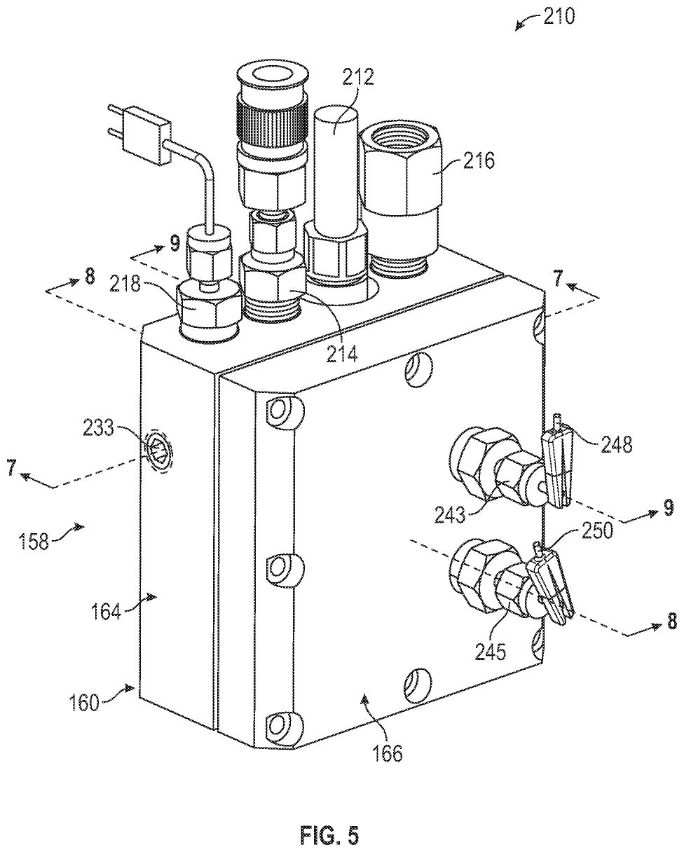

Reference will now follow to FIGS. 5-9 in describing a test fixture 158 in accordance with another non-limiting example. Test fixture 158 includes a housing 160 including a first housing portion 164 and a second housing portion 166. First housing portion 164 supports a battery cell chamber 170. In a non-limiting example, battery cell chamber 170 is generally rectangular in shape. A gasket 174 extends around battery cell chamber 170 and is disposed between first housing portion 164 and second housing portion 166.

In a non-limiting example, a battery assembly 180 is arranged in battery cell chamber 170. Battery assembly 180 includes a first spacer 182, a second spacer 184 and a biasing member 186 arranged between first spacer 182 and second spacer 184. First and second spacers 182 and 184 are formed from an electrically insulative material. A first clamping member 190 is arranged in battery cell chamber 170 directly adjacent to first spacer 182 and second spacer 184. A second clamping member 192 is arranged to apply pressure to first and second spacers 182 and 184 as will be detailed herein. Biasing members 194 urge first clamping member 190 toward second clamping member 192. A battery cell 200 is disposed between second spacer 184 and second clamping member 192.

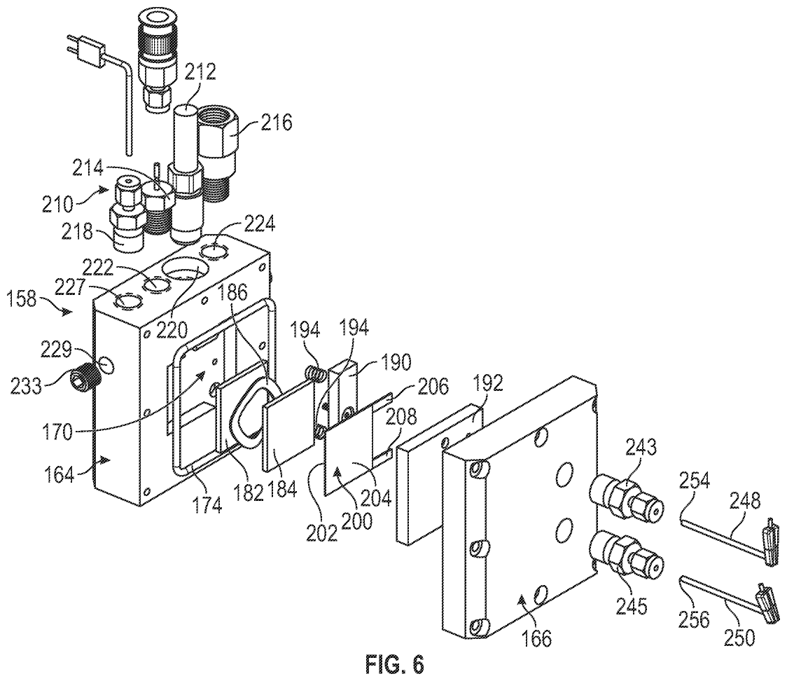

As shown in FIG. 6, battery cell 200 includes an anode 202 and a cathode 204. In a non-limiting example, anode 202 includes an anode tab 206 that extends outwardly of battery cell 200. Cathode 204 includes a cathode tab 208 that likewise extends outwardly of battery cell 200. In a non-limiting example, anode 202 and cathode 204 are separated by an electrically insulating member (not separately labeled) and disposed between first clamping member 190 and second clamping member 192. Liquid electrolyte may be added to battery cell 200. First clamping member 190 supports anode 202 and cathode 204 when forming an electrical connection as will be detailed herein.

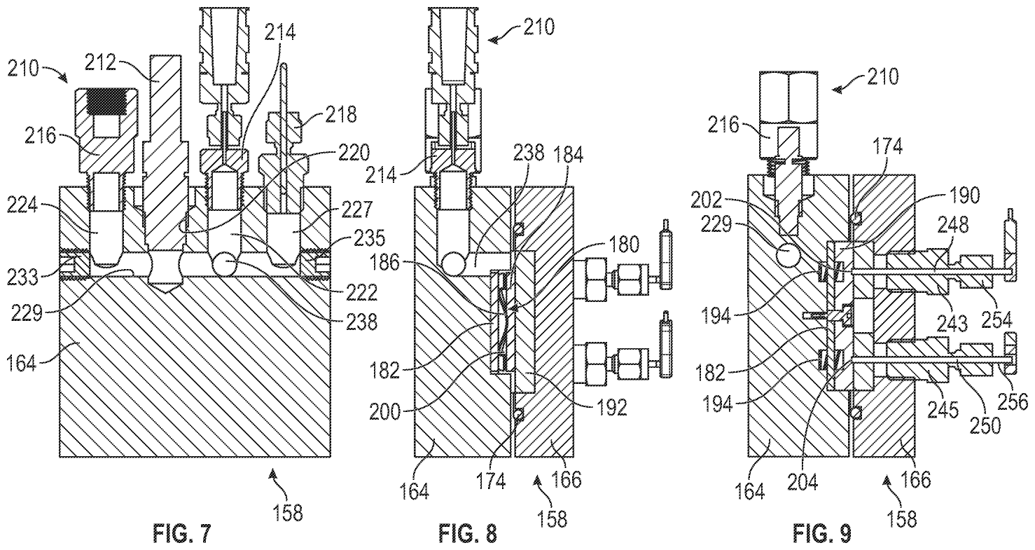

In a non-limiting example, first housing portion 164 includes a plurality of sensor connectors 210 that are fluidically connected with battery cell chamber 170. Plurality of sensor connectors 210 include a gas sampling connector 212, a pressure sensor connector 214, a valve connector 216, and a thermocouple connector 218. In a non-limiting example shown in FIG. 7, a first passage 220 extends between and fluidically connects gas sampling connector 212 and battery cell chamber 170. A second passage 222 extends between and fluidically connects pressure sensor connector 214 and battery cell chamber 170. A third passage 224 extends between and connects valve connector 216 and battery cell chamber 170. A fourth passage 227 extends between and fluidically connects thermocouple connector 218 and battery cell chamber 170.

In a non-limiting example, a linking passage 229 fluidically connects first passage 220, second passage 222, third passage 224, and fourth passage 227. A first plug 233 is arranged at a first end (not separately labeled) of linking passage 229 and a second plug 235 is arranged at a second end (also not separately labeled) of linking passage 229. First and second plugs 233 and 235 close off openings formed during manufacture of first housing portion 164. A gas exit passage 238 guides gases from battery cell chamber 170 into linking passage 229 as shown in FIG. 8.

In a non-limiting example shown in FIG. 9, a first terminal 243 is mounted to second housing portion 166. A second terminal 245 is mounted to second housing portion 166 adjacent to first terminal 243. A first conductor 248 passes through first terminal 243, second housing portion 166, and into second clamping member 192. Similarly, a second conductor 250 passes through second terminal 245, second housing portion 166, and into second clamping member 192. First conductor 248 includes a first electrically conductive element 254 that connects with anode 202 and second conductor 250 includes a second electrically conductive element 256 that connects with cathode 204. In this manner, anode 202 and cathode 204 may be alternately connected to a source of electrical energy and a load in order to cycle battery cell 200 for testing.

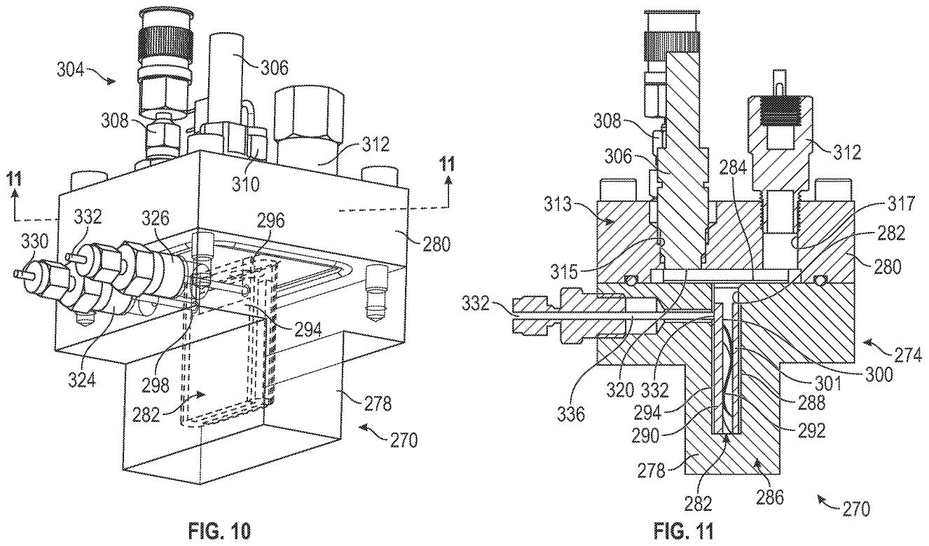

Reference will now follow to FIGS. 10 and 11 in describing a test fixture 270 in accordance with yet another non-limiting example. Test fixture 270 includes a housing 274 having a first housing portion 278 and a second housing portion 280. A battery cell chamber 282 is arranged in first housing portion 278. A gas permeable membrane 284, that forms a liquid barrier, is arranged between first housing portion 278 and second housing portion 280 covering battery cell chamber 282. In a manner similar to that discussed herein, a battery cell assembly 286 is arranged in battery cell chamber 282. Battery cell assembly 286 includes a first spacer 288, a second spacer 290, and a biasing member 292 arranged between first spacer 288 and second spacer 290. A battery cell 294 including a cathode 300 with tab 296 and an anode 301 with tab 298 is arranged directly adjacent to second spacer 290. A cathode 300 and the anode 301 are separated by an electronically insulting separator (not separately labeled). An electrolyte may be added to battery cell chamber 282. In a manner similar to that discussed herein, cathode tab 296 connects with cathode 300 and projects outwardly of battery cells 294. Anode tab 298 connects with anode 301 and likewise projects outwardly from battery cell 294.

In a non-limiting example, a plurality of sensor connectors 304 are provided on second housing portion 280. Plurality of sensor connectors 304 include a gas sampling connector 306, a pressure sensor connector 308, a thermocouple connector 310 and a valve connector 312. A plurality of passages 313 fluidically connect sensor connectors 304 with battery cell chamber 282. Plurality of passages 313 includes a first passage 315 connecting gas sampling connector 306 with battery cell chamber 286 and a second passage 317 fluidically connecting valve connector 312 with battery cell chamber 286. Additional passages (not separately labeled) fluidically connect pressure sensor connector 308 and thermocouple connector 310 with battery cell chamber 286. Plurality of passages 313 extend from each of the plurality of sensor connectors 304 to a recess 320. Recess 320 collects gas that is emitted from battery cell 294.

In a non-limiting example, a first terminal 324 is mounted to first housing portion 278. A second terminal 326 is mounted to first housing portion 278 adjacent to first terminal 324. A first conductor 330 passes through first terminal 324 and first housing portion 278 toward battery cell chamber 282. Similarly, a second conductor 332 passes through second terminal 326 and first housing portion 278 toward battery cell chamber 282. First conductor 330 includes a first electrically conductive element 336 that connects with cathode tab 296 and second conductor 332 includes a second electrically conductive element 337 that connects with anode tab 298. In this manner, cathode 300 and anode 301 may be alternately connected to a source of electrical energy and a load in order to cycle battery cell 294 for testing. While testing, in addition to monitoring voltage and current, gas emitted from battery cell 294 is collected and sampled in order to evaluate battery performance.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A battery cell chemistry test fixture comprising:
a housing including a battery cell chamber;
a first electric terminal electrically connectable to a battery cell in the battery cell chamber;
a second electric terminal electrically connectable to the battery cell in the battery cell chamber; and
a plurality of sensor connectors mounted to the housing, the plurality of sensor connectors including at least a gas sampling connector, a pressure sensor connector, and a valve connector, each of the gas sampling connector, the pressure sensor connector, and the valve connector being fluidically connected with the battery cell chamber.

2. The battery cell chemistry test fixture according to claim 1, wherein the housing includes a first housing portion and a second housing portion coupled to the first housing portion, the battery cell chamber being formed in the first housing portion.

3. The battery cell chemistry test fixture according to claim 2, wherein the first electric terminal is supported on the first housing portion.

4. The battery cell chemistry test fixture according to claim 3, further comprising a biasing member arranged in the battery cell chamber, the biasing member being arranged to urge a first battery cell portion into contact with the first housing portion and establish an electrical connection with the first electric terminal.

5. The battery cell chemistry test fixture according to claim 4, wherein a second battery cell portion is electrically connected to the second housing portion through the biasing member, the second electrical terminal being electrically connected to the second housing portion.

6. The battery cell chemistry test fixture according to claim 5, further comprising an insulating member electrically isolating the first housing portion and the second housing portion.

7. The battery cell chemistry test fixture according to claim 6, wherein the second housing portion includes a first passage fluidically connecting the gas sampling connector and the battery cell chamber, a second passage fluidically connecting the pressure sensor connector with the battery cell chamber, and a third passage fluidically connecting the valve connector and the battery cell chamber.

8. The battery cell chemistry test fixture according to claim 2, wherein the second housing portion includes a central passage fluidically connected to the battery cell chamber.

9. The battery cell chemistry test fixture according to claim 8, further comprising a third housing portion connected to the second housing portion, the plurality of sensor connectors being provided in the third housing portion.

10. The battery cell chemistry test fixture according to claim 9, wherein the third housing portion includes a first passage fluidically connecting the gas sampling connector and the central passage, a second passage fluidically connecting the pressure sensor connector with the central passage, and a third passage fluidically connecting the valve connector and the central passage.

11. The battery cell chemistry test fixture according to claim 10, further comprising a gas permeable membrane disposed between the second housing portion and the third housing portion, the gas permeable membrane forming a liquid barrier isolating the central passage from each of the first passage, the second passage, and the third passage.

12. The battery cell chemistry test fixture according to claim 3, wherein the second electric terminal is supported on the second housing portion.

13. The battery cell chemistry test fixture according to claim 12, wherein each of the gas sampling connector, the pressure sensor connector, and the valve connector is mounted to the first housing portion.

14. The battery cell chemistry test fixture according to claim 13, a first clamping block arranged in the battery cell chamber, the first clamping block being biased toward the second housing portion.

15. The battery cell chemistry test fixture according to claim 14, further comprising a second clamping block arranged in the second housing portion, the first clamping block being biased toward the second clamping block.

16. The battery cell chemistry test fixture according to claim 15, further comprising a battery cell arranged in the battery cell chamber, the battery cell including a first terminal and a second terminal, the first terminal and the second terminal being arranged between the first clamping block and the second clamping block.

17. The battery cell chemistry test fixture according to claim 16, a first conductor including a first electrically conductive member extending through the first electric terminal and a second conductor including a second electrically conductive member extending through the second electric terminal, the first electrically conductive member engaging the first terminal and the second electrically conductive member engaging the second terminal.

18. The battery cell chemistry test fixture according to claim 17, further comprising a biasing member arranged in the battery cell chamber, the biasing member being arranged to urge a battery cell toward the second housing portion.

19. The battery cell chemistry test fixture according to claim 18, wherein the biasing member is arranged between first and second non-electrically conductive spacers.

20. The battery cell chemistry test fixture according to claim 3, wherein each of the first electric terminal and the second electric terminal are connected to the first housing portion.
